(19) United States
(12) Patent Application Publication
(10) Pub. No.: US 2026/0329239 A1
(43) Pub. Date: Oct. 22, 2026

(54) TINYML-BASED MOTOR CONDITION MONITORING METHOD AND APPARATUS

(71) Applicant: Zhongshan Broad-Ocean Motor Co., Ltd., Zhongshan (CN)

(72) Inventor: Jizhong WANG, Zhongshan (CN)

(21) Appl. No.: 19/694,930

(22) Filed: Jun. 1, 2026

Related U.S. Application Data
(63) Continuation-in-part of application No. PCT/CN2025/097396, filed on May 27, 2025.

(30) Foreign Application Priority Data
Oct. 12, 2024 (CN) 202411426390.9

(51) Int. Cl. G05B 13/02

(52) U.S. Cl. CPC G05B 13/0265

(57) ABSTRACT

A TinyML-based motor condition monitoring method, applied to a microcontroller unit of an edge device in an HVAC system, and the method including: collecting real-time operating parameters of a monitored motor; preprocessing the real-time operating parameters to convert the real-time operating parameters into input data having a preset format, where the preset format is a data input format of a TinyML model pre-deployed in the microcontroller unit; and inputting the input data into the TinyML model, and outputting, by the TinyML model, a real-time condition monitoring result of the monitored motor. The disclosure achieves motor condition monitoring by the microcontroller unit of the edge device on the motor side, without requiring real-time transmission of data to a cloud platform for determination, thereby reducing monitoring costs and improving data security.

### CROSS-REFERENCE TO RELATED APPLICATIONS

This application is a continuation-in-part of International Patent Application No. PCT/CN2025/097396 with an international filing date of May 27, 2025, designating the United States, now pending, further claims foreign priority benefits to Chinese Patent Application No. 202411426390.9 filed Oct. 12, 2024. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, MA 02142.

### BACKGROUND

The disclosure relates to the field of motor monitoring, and more particularly to a TinyML-based motor condition monitoring method and apparatus.

In residential HVAC systems, the motor is a core component for operation and control. Electronically Commutated Motors (ECMs) are commonly used as start-up motors for devices such as air conditioners.

To enable online real-time monitoring of ECM abnormal conditions or prediction of motor life, some machine learning solutions have been deployed. These solutions typically involve collecting large amounts of data and transmitting the data to a cloud computing platform, where machine learning is performed. However, such approaches require a full-time network connection (e.g., Wi-Fi, 4G/5G) for the ECM to transmit data in real time. The need for an additional cloud computing platform and real-time data transmission results in high costs and poses a risk that the data may be intercepted during remote transmission.

In residential HVAC systems, due to high hardware costs and data security concerns, it is impractical to maintain a full-time connection to a cloud-based platform for training, refining, and then using a machine learning model to monitor the HVAC system. Moreover, such systems are difficult to set up and maintain. Therefore, there is a need for a lightweight solution that can perform motor condition monitoring locally, determining whether a motor is abnormal or predicting motor life, thereby addressing the high cost and data security issues of existing motor condition monitoring solutions.

### SUMMARY

One objective of the disclosure is to provide a TinyML-based motor condition monitoring method and apparatus, so as to solve the technical problems of high cost and data insecurity in existing motor condition monitoring methods.

According to a first aspect, the disclosure provides a TinyML-based motor condition monitoring method, applied to a microcontroller unit of an edge device in an HVAC system, and the method comprising: collecting real-time operating parameters of a monitored motor; preprocessing the real-time operating parameters to convert the real-time operating parameters into input data having a preset format, where the preset format is a data input format of a TinyML model pre-deployed in the microcontroller unit; and inputting the input data into the TinyML model, and outputting, by the TinyML model, a real-time condition monitoring result of the monitored motor.

In the TinyML-based motor condition monitoring method of the disclosure, by collecting real-time operating parameters of a monitored motor, preprocessing the real-time operating parameters to convert them into input data having a preset format, inputting the input data into the TinyML model pre-deployed in the microcontroller unit, and outputting, by the TinyML model, a real-time condition monitoring result of the monitored motor, the method utilizes the characteristics that the TinyML model is small in size and the microcontroller unit of the edge device in the HVAC system has computational capability, and directly deploys the TinyML model on the microcontroller unit of the edge device. Motor condition monitoring is thus carried out by the microcontroller unit of the edge device on the motor side, without requiring real-time transmission of data to a cloud platform for determination, thereby reducing monitoring costs and improving data security.

In a class of this embodiment, the method further comprises: after outputting the real-time condition monitoring result of the monitored motor by the TinyML model, adjusting an operation action of the monitored motor according to the real-time condition monitoring result.

In this manner, by adjusting the operation action of the motor according to the real-time condition monitoring result, the operating state of the motor can be adjusted in a timely manner, thereby preventing the occurrence of faults or accidents.

In a class of this embodiment, adjusting the operation action of the monitored motor according to the real-time condition monitoring result comprises: determining whether the real-time condition monitoring result is a first type of abnormal condition; and if the real-time condition monitoring result is the first type of abnormal condition, changing a rotation speed or a start/stop status of the monitored motor, or outputting alarm information.

In this manner, a rapid response to a minor abnormal condition can be made, and fault deterioration can be prevented by adjusting operating parameters or issuing an alarm.

In a class of this embodiment, adjusting the operation action of the monitored motor according to the real-time condition monitoring result further comprises: determining whether the real-time condition monitoring result is a second type of abnormal condition; and if the real-time condition monitoring result is the second type of abnormal condition, sending maintenance warning information to a third-party platform, where the maintenance warning information comprises the real-time condition monitoring result, an identity identifier of the monitored motor, and location information of the monitored motor.

In this manner, when a more severe abnormality occurs, maintenance personnel can be notified in a timely manner, thereby reducing the impact of the fault on system operation and accelerating maintenance response time.

In a class of this embodiment, adjusting the operation action of the monitored motor according to the real-time condition monitoring result further comprises: determining whether the real-time condition monitoring result is a third type of abnormal condition; and if the real-time condition monitoring result is the third type of abnormal condition, sending the collected real-time operating parameters to the third-party platform, and causing the third-party platform to re-determine the condition of the monitored motor according to the real-time operating parameters using a preset artificial intelligence model, where the preset artificial intelligence model has a larger scale or higher recognition accuracy than the TinyML model.

In this manner, for complex or uncertain abnormal conditions, the corresponding real-time operating parameters are transmitted to a third-party platform, and a more complex artificial intelligence model is used for in-depth analysis, thereby improving the accuracy of fault diagnosis.

In this manner, by performing a sliding discrete Fourier transform on the real-time operating parameters, abnormal characteristics during motor operation can be more accurately captured in the frequency domain, thereby improving the sensitivity and accuracy of fault detection.

In a class of this embodiment, the TinyML model is a classification model based on a convolutional neural network trained by supervised learning, where training samples comprise three-phase currents corresponding to a shaft balanced state of the motor and three-phase currents corresponding to a shaft imbalanced state of the motor, and the real-time operating parameters are real-time three-phase currents of the monitored motor; and correspondingly, inputting the input data into the TinyML model and outputting, by the TinyML model, the real-time condition monitoring result of the monitored motor comprises: inputting the input data into the TinyML model, and outputting, by the TinyML model, a classification result of the monitored motor; and if the classification result is the shaft balanced state, outputting the real-time condition monitoring result as a normal state, or if the classification result is the shaft imbalanced state, outputting the real-time condition monitoring result as an abnormal state.

In this manner, by using three-phase currents as input data and classifying the shaft balanced state and the shaft imbalanced state of the motor based on a convolutional neural network, the current balanced state of the motor can be determined, thereby achieving high-precision fault detection.

In a class of this embodiment, the classification model employs a multilayer perceptron; the multilayer perceptron comprises an input layer, hidden layers, and an output layer; the input layer is configured to receive features of the input data; and the hidden layers and the output layer use a nonlinear activation function, and input and output of each of the hidden layers and the output layer are respectively expressed as:

$${x}_{j}^{d + 1} = {\sum }_{i = 1}^{n} {y}_{i}^{d} {w}_{ij}^{d} - {α}_{j}^{d + 1}$$

$${y}_{j}^{d} = \frac{1}{1 + {e}^{- {x}_{j}^{d}}}$$

where

$${x}_{j}^{d + 1}$$

is an input received by an j-th neuron in layer d+1, n is a number of input features,

$${y}_{i}^{d}$$

is an output of an i-th neuron in layer d,

$${w}_{ij}^{d}$$

is a weight from the i-th neuron in layer d to the j-th neuron in layer d+1,

$${α}_{j}^{d + 1}$$

represents a threshold of the j-th neuron in layer d+1, and

$${x}_{j}^{d}$$

is an input received by the j-th neuron in layer d; and
the MLP employs a backpropagation algorithm to train weights between neurons in each layer, with a weight update formula as follows:

$${w}_{ij}^{( h )} ( new ) = {w}_{i j}^{( h )} ( old ) - μ \frac{\partial {Δ}^{2}}{\partial {w}_{ij}^{( h )}}$$

where

$${w}_{ij}^{( h )} ( new )$$

is an updated weight in layer h,

$${w}_{ij}^{( h )}$$

is a weight in layer h before updating, μ is a learning rate, and Δ is a difference between a current output and a target output of the output layer.

In this manner, using the multilayer perceptron as the classification model has the advantages of simple implementation a small footprint, making it suitable for resource-constrained MCUs, thereby facilitating deployment on the microcontroller unit of an edge device in an HVAC system.

According to a second aspect, the disclosure provides a TinyML-based motor condition monitoring is a applied to a microcontroller unit of an edge device in an HVAC system, comprising: a parameter acquisition module configured to collect real-time operating parameters of a monitored motor; a data preprocessing module configured to preprocess the real-time operating parameters to convert the real-time operating parameters into input data having a preset format, where the preset format is a data input format of a TinyML model pre-deployed in the microcontroller unit; and a result detection module configured to input the input data into the TinyML model, and output, by the TinyML model, a real-time condition monitoring result of the monitored motor.

According to a third aspect, the disclosure provides a computer device, comprising: a memory and a processor, where the memory and the processor are communicatively connected to each other, the memory stores computer instructions, and the processor executes the computer instructions to perform the TinyML-based motor condition monitoring method according to the first aspect or any embodiment thereof.

According to a fourth aspect, the disclosure provides a computer-readable storage medium, where the computer-readable storage medium stores computer instructions, and the computer instructions are configured to cause a computer to perform the TinyML-based motor condition monitoring method according to the first aspect or any embodiment thereof.

### BRIEF DESCRIPTION OF THE DRAWINGS

FIG. 1 is a flowchart diagram of a TinyML-based motor condition monitoring method according to one embodiment of the disclosure;

FIG. 2 is a flowchart diagram of a TinyML-based motor condition monitoring method according to another embodiment of the disclosure;

FIG. 3 is a schematic diagram of a multilayer perceptron according to one embodiment of the disclosure;

FIG. 4 is a schematic diagram showing feature data of three-phase currents in a shaft balanced state of a motor according to one embodiment of the disclosure;

FIG. 5 is a schematic diagram showing feature data of three-phase currents in a shaft imbalanced state of a motor according to one embodiment of the disclosure;

FIG. 6 is a structural block diagram of a TinyML-based motor condition monitoring apparatus according to one embodiment of the disclosure; and

FIG. 7 is a hardware structure diagram of a computer device according to one embodiment of the disclosure.

### DETAILED DESCRIPTION

To further illustrate the disclosure, embodiments detailing a TinyML-based motor condition monitoring method and apparatus are described below. It should be noted that the following embodiments are intended to describe and not to limit the disclosure.

Tiny Machine Learning (TinyML) belongs to the intersection of machine learning and embedded IoT devices. It is an emerging engineering discipline with the potential to revolutionize many industries.

The Microcontroller Units (MCUs) of Electronically Commutated Motors (ECMs) used in Heating, Ventilation, and Air Conditioning (HVAC) systems have become increasingly powerful with technological development. Whether the same MCU used for motor control or other dedicated MCUs, they can execute AI/ML functions locally without requiring a network connection. Based on the development of HVAC systems and TinyML models, the disclosure provide a TinyML-based motor condition monitoring method that performs machine analysis at the edge device to reduce motor monitoring costs and ensure data security.

According to one embodiment of the disclosure, a method for motor condition monitoring based on TinyML is provided. It should be noted that the steps illustrated in the flowcharts of the accompanying drawings may be executed in a computer system having a set of computer-executable instructions. Moreover, although a logical order is shown in the flowcharts, in certain instances the steps shown or described may be performed in an order different from that set forth herein.

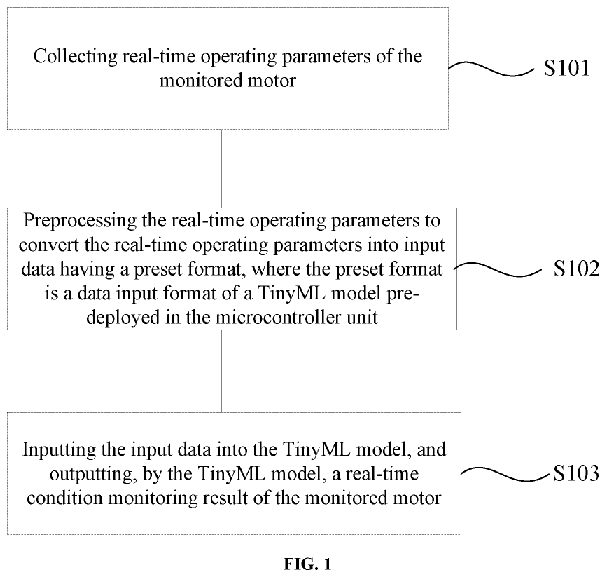

In this embodiment, a method for motor condition monitoring based on TinyML is provided, applied to a microcontroller unit of an edge device in an HVAC system, including a microcontroller unit that controls an electronically commutated motor itself or a microcontroller unit of other dedicated edge devices. As shown in FIG. 1, the method comprises the following steps:

Step S101: collecting real-time operating parameters of the monitored motor.

Optionally, the monitored motor is an ECM motor with vector control in an HVAC system, which comprises a Bluetooth or high-speed optically isolated communication board.

The real-time operating parameters are collected at a set frequency by sensors built into the ECM motor or by additionally deployed sensors.

The real-time operating parameters comprise, for example, speed, torque, and power. Multiple real-time operating parameters may be captured synchronously.

Step S102: preprocessing the real-time operating parameters to convert the real-time operating parameters into input data having a preset format, where the preset format is a data input format of a TinyML model pre-deployed in the microcontroller unit.

Optionally, different TinyML models are selected according to different motors and operational fault scenarios in the HVAC field. The functions of the TinyML models are primarily to analyze and monitor motor conditions, including identifying motor anomalies, faults, or predicting motor life, among others.

Different motors and operational fault scenarios correspond to deploying different types of TinyML models. For example, airflow blockage detection and shaft imbalance require significantly different TinyML models. Moreover, multiple TinyML models may be run in parallel to improve detection accuracy and to handle multiple faults simultaneously.

The real-time operating parameters and data input formats required by different types of TinyML models may also differ. For instance, in a shaft imbalance anomaly detection scenario, the TinyML model is constructed based on a convolutional neural network, the collected real-time operating parameter is three-phase current of the motor, and the preprocessing step primarily involves a discrete Fourier transform. Each anomaly scenario may require a different model or a different preprocessing step for data conversion. In other examples, the preprocessing step further includes outlier removal, data normalization, and the like.

Step S103: inputting the input data into the TinyML model, and outputting, by the TinyML model, a real-time condition monitoring result of the monitored motor.

It should be understood that the TinyML model needs to be trained using a pre-collected dataset, preferably using supervised training because it may be easier to perform, but other training methods may also be used depending on the particular model being trained. Multiple types of TinyML models are set up for joint training. After training is completed, a random subset of the collected dataset is used to verify the accuracy of the TinyML models, and the TinyML model with the best predictive accuracy is deployed to the microcontroller unit of the edge device in the HVAC system. The TinyML model and the motor control code are combined into deployable firmware and flashed onto the microcontroller unit of the edge device. Accordingly, field testing can be performed to further verify the efficiency of the model in its natural environment.

Since the TinyML model deployed in the microcontroller unit has been trained, screened, and validated, during actual monitoring, it is only necessary to preprocess the real-time operating parameters collected in real time and convert them into corresponding input data. Then, the TinyML model in the microcontroller unit can directly output a real-time condition monitoring result, thereby determining whether the motor has an abnormality or fault.

According to one embodiment of the disclosure, the TinyML-based motor condition monitoring method collects real-time operating parameters of a monitored motor, preprocesses the real-time operating parameters to convert them into input data having a preset format, inputs the input data into a TinyML model pre-deployed in a microcontroller unit, and outputs, via the TinyML model, a real-time condition monitoring result of the monitored motor. By utilizing the characteristics that the TinyML model has a small size and that the microcontroller unit of the edge device in the HVAC system possesses computational capability, the TinyML model is directly deployed on the microcontroller unit of the edge device. Motor condition monitoring is thus carried out by the microcontroller unit of the edge device at the motor side, without requiring real-time transmission of data to a cloud platform for determination, thereby reducing monitoring costs and improving data security.

In some embodiments, after outputting, via the TinyML model, the real-time condition monitoring result of the monitored motor in step S103, the method further comprises:
step S104: adjusting an operation action of the monitored motor according to the real-time condition monitoring result.

Specifically, the microcontroller unit of the edge device is used to control the monitored motor without requiring any additional external equipment. Thus, it can be used for smaller motors (e.g., in residential air conditioners or furnaces) and operates fully autonomously. This approach offers the significant advantage of allowing the MCU to take corresponding actions to control the motor based on the real-time condition monitoring result, such as setting an alarm, reducing motor speed, or stopping the motor, depending on the severity of the detected anomaly.

The severity of the anomaly can be obtained from the real-time condition monitoring result. For example, the output of the TinyML model may include three outcomes: normal condition, a first type of abnormal condition, and a second type of abnormal condition, where the severity of the second type of abnormal condition is greater than that of the first type of abnormal condition. Furthermore, to achieve more precise control of the motor, more finely graded levels of anomalies may also be provided.

In this manner, by adjusting the operation action of the motor according to the real-time condition monitoring result, the operating condition of the motor can be adjusted in a timely manner, thereby preventing the occurrence of faults or accidents.

In some embodiments, adjusting the operation action of the monitored motor according to the real-time condition monitoring result in step S104 comprises:
step S1041: determining whether the real-time condition monitoring result is a first type of abnormal condition; and
step S1042: if the real-time condition monitoring result is the first type of abnormal condition, changing a rotation speed or a start/stop status of the monitored motor, or outputting alarm information.

In this embodiment, the deployed TinyML model is capable of classifying the output real-time condition monitoring result into at least two categories: a normal condition and a first type of abnormal condition. When the output result, i.e., the real-time condition monitoring result, is the first type of abnormal condition, the rotation speed or start/stop status of the monitored motor is changed, or alarm information is output, so as to prevent the fault from worsening.

In some embodiments, adjusting the operation action of the monitored motor according to the real-time condition monitoring result in step S104 further comprises:
step S1043: determining whether the real-time condition monitoring result is a second type of abnormal condition; and
step S1044: if the real-time condition monitoring result is the second type of abnormal condition, sending maintenance warning information to a third-party platform, where the maintenance warning information comprises the real-time condition monitoring result, an identity identifier of the monitored motor, and location information of the monitored motor.

In this embodiment, the deployed TinyML model is capable of classifying the output real-time condition monitoring result into at least two categories: a normal condition, and a second type of abnormal condition. The severity of the second type of abnormal condition is greater than that of the first type of abnormal condition. When the output result, i.e., the real-time condition monitoring result, is the second type of abnormal condition, maintenance warning information is sent to a third-party platform. A maintenance technician can quickly locate the maintenance issue and the position of the motor using the real-time condition monitoring result, the identity identifier of the monitored motor, and the location information of the monitored motor included in the maintenance warning information, thereby facilitating post-maintenance of the motor.

In this manner, when a more severe anomaly occurs, maintenance personnel can be notified in a timely manner, reducing the impact of the fault on system operation and accelerating maintenance response time.

In some embodiments, adjusting the operation action of the monitored motor according to the real-time condition monitoring result in step S104 further comprises:
step S1045: determining whether the real-time condition monitoring result is a third type of abnormal condition; and
step S1046: if the real-time condition monitoring result is the third type of abnormal condition, sending the collected real-time operating parameters to a third-party platform, and re-determining, by the third-party platform using a preset artificial intelligence model, the condition of the monitored motor according to the real-time operating parameters, where the preset artificial intelligence model has a larger scale or higher recognition accuracy than the TinyML model.

Specifically, the preset artificial intelligence model is a machine learning model or AI model having a larger scale and more powerful performance.

The third type of abnormal condition is a result recognized by the edge device, and the degree of abnormality of the third type of abnormal condition is less than that of the first type of abnormal condition. Due to the limited computational resources of the edge device itself, when the recognition result is the third type of abnormal condition, directly determining that an abnormality exists may not be sufficiently accurate. In this case, the real-time operating parameters are transmitted as a data stream to a third-party platform (e.g., a cloud computing platform) by adding a network module or Bluetooth, so that a more powerful machine learning model or AI model can be used for more detailed analysis, thereby obtaining a more accurate result.

In this manner, for complex or uncertain abnormal conditions, the corresponding real-time operating parameters are transmitted to a third-party platform, and a more complex artificial intelligence model is used to perform in-depth analysis, thereby improving the accuracy of fault diagnosis.

In some embodiments, in step S102, preprocessing the real-time operating parameters to convert the real-time operating parameters into input data having a preset format comprises:
step S1021: performing a sliding discrete Fourier transform on the real-time operating parameters to convert the real-time operating parameters into input data having the preset format.

In this manner, by performing the sliding discrete Fourier transform on the real-time operating parameters to convert them into input data of the TinyML model, frequency domain analysis can be performed based on the input data, thereby accurately capturing abnormal characteristics during motor operation and improving the sensitivity and accuracy of fault detection.

In some embodiments, the TinyML model is a classification model based on a convolutional neural network trained by supervised learning, where training samples comprise three-phase currents corresponding to a shaft balanced state of the motor and three-phase currents corresponding to a shaft imbalanced state of the motor, and the real-time operating parameters are real-time three-phase currents of the monitored motor.

Correspondingly, in step S103, inputting the input data into the TinyML model and outputting, by the TinyML model, the real-time condition monitoring result of the monitored motor comprises:
step S1031: inputting the input data into the TinyML model, and outputting, by the TinyML model, a classification result of the monitored motor; and
step S1032: if the classification result is the shaft balanced state, then the output real-time condition monitoring result is a normal state; if the classification result is the shaft imbalanced state, then the output real-time condition monitoring result is an abnormal state.

Further, in some embodiments, the classification model employs a multilayer perceptron (MLP). The MLP includes an input layer, hidden layers, and an output layer. The input layer is configured to receive features of the input data. The hidden layers and the output layer use a nonlinear activation function. The input and output of each hidden layer and the output layer are respectively expressed as:

$${x}_{j}^{d + 1} = {\sum }_{i = 1}^{n} {y}_{i}^{d} {w}_{ij}^{d} - {α}_{j}^{d + 1} \\ {y}_{j}^{d} = \frac{1}{1 + {e}^{- {x}_{j}^{d}}}$$

where

$${x}_{j}^{d + 1}$$

is an input received by the j-th neuron in layer d+1, n is the number of input features,

$${y}_{i}^{d}$$

is an output of the i-th neuron in layer d,

$${w}_{ij}^{d}$$

is a weight from the i-th neuron in layer d to the j-th neuron in layer d+1,

$${α}_{j}^{d + 1}$$

represents a threshold of the j-th neuron in layer d+1, and

$${x}_{j}^{d}$$

is an input received by the j-th neuron in layer d.

The MLP employs a backpropagation algorithm to train the weights between neurons in each layer, with a weight update formula as follows:

$${w}_{ij}^{( h )} ( new ) = {w}_{ij}^{( h )} ( old ) - μ \frac{\partial {Δ}^{2}}{\partial {w}_{ij}^{( h )}}$$

where

$${w}_{ij}^{( h )} ( new )$$

is an updated weight in layer h,

$${w}_{ij}^{( h )} ( old )$$

is a weight in layer h before updating, μ is a learning rate, and Δ is a difference between a current output and a target output of the output layer.

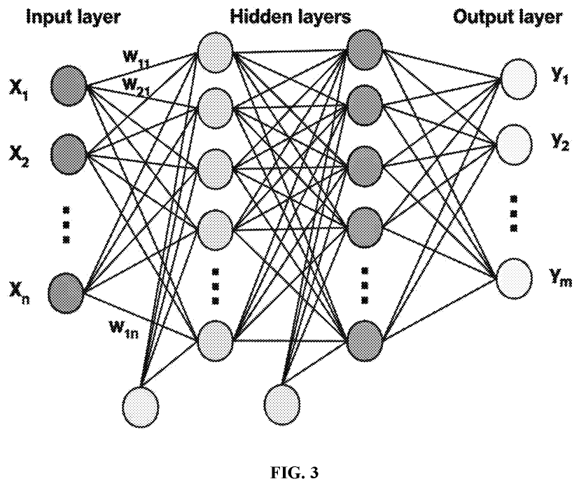

Specifically, the multilayer perceptron (MLP) is a supervised feedforward neural network commonly used in EdgeAI applications. As shown in FIG. 3, the MLP comprises multiple layers, including an input layer, an output layer, and a plurality of hidden layers, where each layer contains a set of perceptual elements called neurons. FIG. 3 illustrates an MLP having two hidden layers, an input layer, and an output layer. In the network, each node exhibits a certain amount of bias. The input layer contains n input variables X={x₁, x₂, . . . , xₙ}, and the output layer contains m output variables Y={y₁, y₂, . . . , yₘ}.

The hidden layers and the output layer use a nonlinear activation function (sigmoid function). The total input received by neuron j in layer d+1 can be expressed as:

$${x}_{j}^{d + 1} = {\sum }_{i = 1}^{n} {y}_{i}^{d} {w}_{ij}^{d} - {α}_{j}^{d + 1}$$

The output of a neuron in any layer except the input layer can be expressed as:

$${y}_{j}^{d} = \frac{1}{1 + {e}^{- {x}_{j}^{d}}}$$

To train the multilayer perceptron, a backpropagation algorithm is implemented. This is a supervised learning method because, during the learning phase, the output of the multilayer perceptron is compared with a known desired signal to indicate how well the network is performing.

The backpropagation algorithm is a form of the steepest descent algorithm, i.e., gradient descent, in which an error signal A, which is the difference between the current output and the target output of the output layer, is used to adjust the weight in each neuron in proportion to the gradient of the squared error with respect to that weight in the output layer, and is then used to adjust the weights in the hidden layers, always propagating back through the network to the input. Thus, although the neural network operates on input signals to produce outputs in a completely feedforward manner, during the learning process, the resulting error signal propagates from the network's output back to the input to adjust the weights. That is, the weight update formula for the hidden layer in layer h is:

$${w}_{ij}^{( h )} ( new ) = {w}_{ij}^{( h )} ( old ) - μ \frac{\partial {Δ}^{2}}{\partial {w}_{ij}^{( h )}}$$

In this manner, using the multilayer perceptron as the classification model has the advantages of simple implementation and a small footprint, making it suitable for resource-constrained MCUs, thereby facilitating deployment on the microcontroller unit of an edge device in an HVAC system.

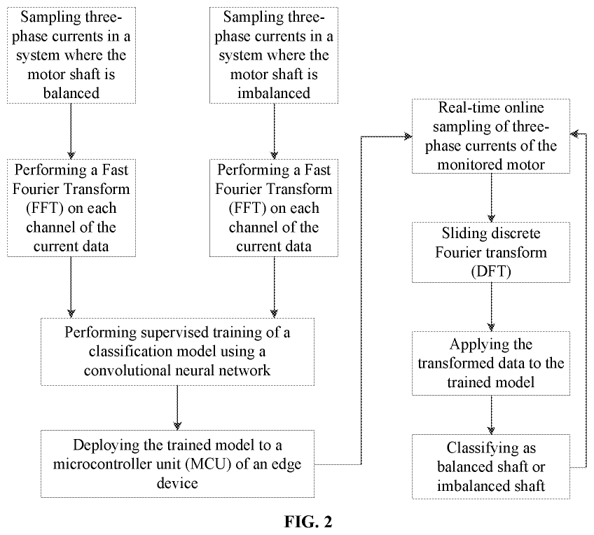

As shown in FIG. 2, in an embodiment of the disclosure, the selected TinyML model serves as a classification model configured to classify a state of a motor shaft as either an unbalanced state or a balanced state based on features of three-phase currents. Training samples are obtained by sampling and labeling from a system in which the motor shaft is balanced (i.e., under normal operation) and from a system in which the motor shaft is unbalanced (i.e., under faulty operation), respectively.

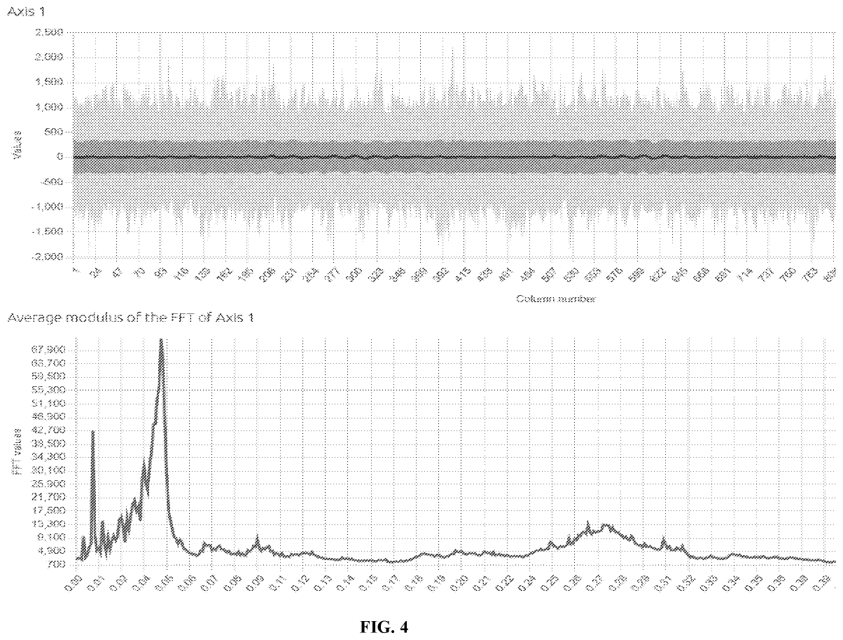

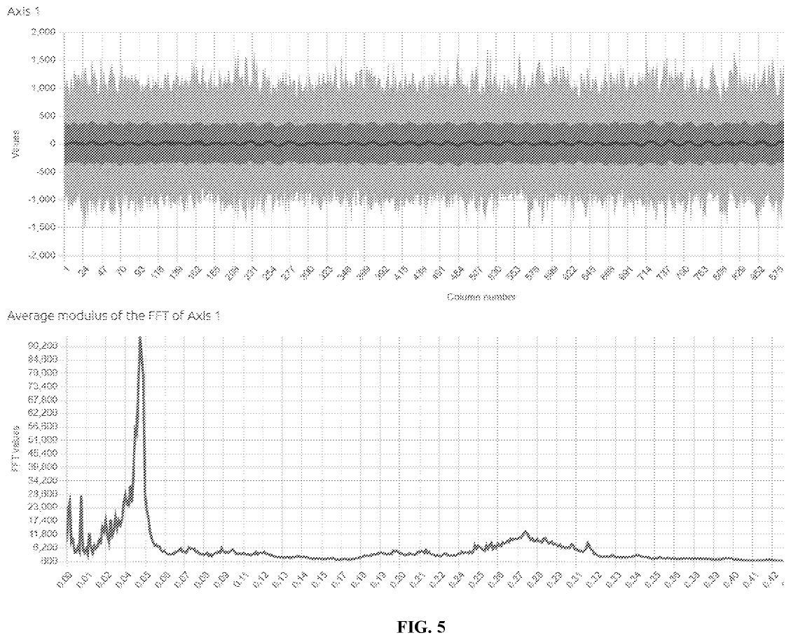

Feature data of the three-phase currents under the balanced (normal) condition is illustrated in FIG. 4, and feature data of the three-phase currents under the unbalanced condition is illustrated in FIG. 5.

A multi-layer perceptron (MLP) is employed as the TinyML model. The trained TinyML model is validated using a random subset of the collected training samples, and the TinyML model achieving the highest prediction accuracy is selected for deployment onto a microcontroller unit (MCU) of an edge device.

In one example, various parameters of the selected TinyML model are as follows:

| | | | | Minimum | |
|---|---|---|---|---|---|
| | Balanced | | Flash | Learning | Execution |
| Score | Accuracy | RAM | Memory | Iterations | Time |
| 93.98% | 99.10% | 12.9 kb | 4.2 kb | 110 | 11.8 ms |

As can be seen from the table above, when a multi-layer perceptron (MLP) is used as the TinyML model, the required runtime computational resources and storage resources are relatively low while achieving high accuracy. Therefore, the model is suitable for deployment on edge devices to realize edge detection.

The TinyML model and the motor control code will be combined into deployable firmware and flashed onto the MCU of the edge device. Accordingly, field testing can be performed to further validate the model efficiency in its natural environment.

During real-time monitoring, input data conforming to the data format of the TinyML model is obtained by performing a sliding discrete Fourier transform on real-time sampled three-phase currents. The input data is then fed into the TinyML model, which classifies the motor being monitored as either a shaft balanced state or a shaft unbalanced state based on features of the real-time sampled three-phase currents. If the classification result is the shaft balanced state, the output real-time condition monitoring result is a normal state; if the classification result is the shaft unbalanced state, the output real-time condition monitoring result is an abnormal state.

In an embodiment of the disclosure, by using three-phase currents as input data and constructing a TinyML model based on a multi-layer perceptron to classify the shaft balanced state and the shaft unbalanced state of the motor, the current balance state of the motor can be determined, thereby achieving high-precision fault detection.

It should be appreciated that in other embodiments, for different scenarios (e.g., airflow blockage detection), different input data, different TinyML models, and different data transformations may be deployed.

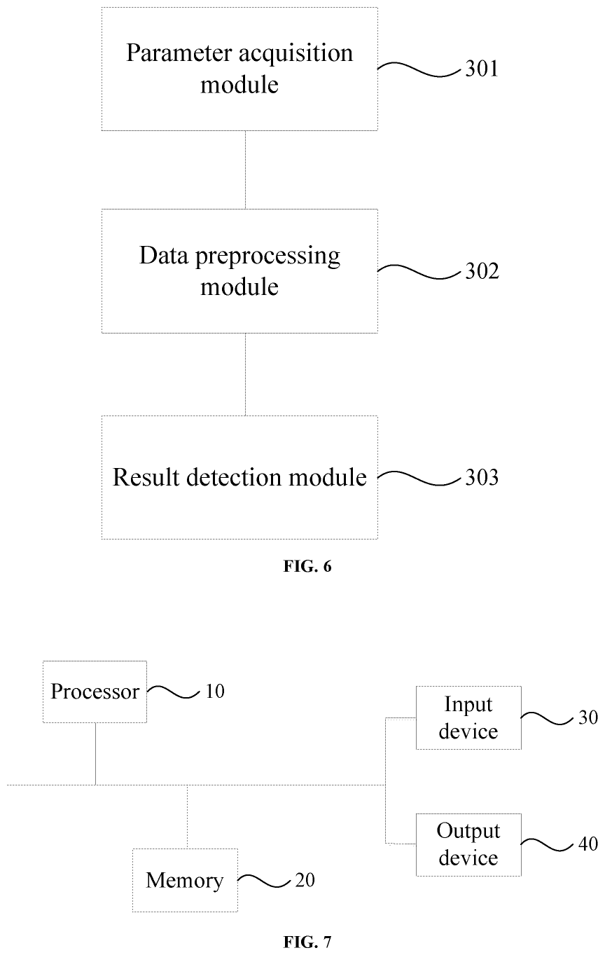

The disclosure further provides a TinyML-based motor condition monitoring apparatus, applied to a microcontroller unit of an edge device in an HVAC system. As shown in FIG. 6, the apparatus comprises:
a parameter acquisition module 301 configured to collect real-time operating parameters of a monitored motor;
a data preprocessing module 302 configured to preprocess the real-time operating parameters to convert the real-time operating parameters into input data having a preset format, where the preset format is a data input format of a TinyML model pre-deployed in the microcontroller unit; and
a result detection module 303 configured to input the input data into the TinyML model and output, via the TinyML model, a real-time condition monitoring result of the monitored motor.

In an embodiment of the disclosure, the TinyML-based motor condition monitoring apparatus collects real-time operating parameters of a monitored motor, preprocesses the real-time operating parameters to convert them into input data having a preset format, inputs the input data into a TinyML model pre-deployed in a microcontroller unit, and outputs, via the TinyML model, a real-time condition monitoring result of the monitored motor. By utilizing the characteristics that the TinyML model is small in size and that the microcontroller unit of the edge device in the HVAC system possesses computational capability, the TinyML model is directly deployed on the microcontroller unit of the edge device. Motor condition monitoring is thus carried out by the microcontroller unit of the edge device on the motor side, without requiring real-time transmission of data to a cloud platform for determination, thereby reducing monitoring costs and improving data security.

Further, the TinyML-based motor condition monitoring apparatus further comprises:
an action control module configured to adjust an operation action of the monitored motor according to the real-time condition monitoring result.

Further, the action control module comprises:
a first abnormality determination module configured to determine whether the real-time condition monitoring result is a first type of abnormal condition; and
a first control output module configured to, if the real-time condition monitoring result is the first type of abnormal condition, change a rotation speed or a start/stop status of the monitored motor, or output alarm information.

Further, the action control module comprises:
a second abnormality determination module configured to determine whether the real-time condition monitoring result is a second type of abnormal condition; and
a second control output module configured to, if the real-time condition monitoring result is the second type of abnormal condition, send maintenance warning information to a third-party platform, where the maintenance warning information comprises the real-time condition monitoring result, an identity identifier of the monitored motor, and location information of the monitored motor.

Further, the action control module comprises:
a third abnormality determination module configured to determine whether the real-time condition monitoring result is a third type of abnormal condition; and
a third control output module configured to, if the real-time condition monitoring result is the third type of abnormal condition, send the collected real-time operating parameters to a third-party platform, and cause the third-party platform to re-determine the condition of the monitored motor according to the real-time operating parameters using a preset artificial intelligence model, where the preset artificial intelligence model has a larger scale or higher recognition accuracy than the TinyML model.

Further, the TinyML model is a classification model based on a convolutional neural network trained by supervised learning, where training samples comprise three-phase currents corresponding to a shaft balanced state of the motor and three-phase currents corresponding to a shaft imbalanced state of the motor, and the real-time operating parameters are real-time three-phase currents of the monitored motor.

Correspondingly, the result detection module 303 comprises:
a data input module configured to input the input data into the TinyML model and output, via the TinyML model, a classification result of the monitored motor; and
an abnormality confirmation block configured to, if the classification result is the shaft balanced state, output the real-time condition monitoring result as a normal state, and if the classification result is the shaft imbalanced state, output the real-time condition monitoring result as an abnormal state.

Further, the classification model employs a multilayer perceptron (MLP). The MLP includes an input layer, hidden layers, and an output layer. The input layer is configured to receive features of the input data. The hidden layers and the output layer use a nonlinear activation function. The input and output of each hidden layer and the output layer are respectively expressed as:

$${x}_{j}^{d + 1} = {\sum }_{i = 1}^{n} {y}_{i}^{d} {w}_{ij}^{d} - {α}_{j}^{d + 1} \\ {y}_{j}^{d} = \frac{1}{1 + {e}^{- {x}_{j}^{d}}}$$

where

$${x}_{j}^{d + 1}$$

is an input received by the j-th neuron in layer d+1, n is the number of input features,

$${y}_{i}^{d}$$

is an output of the i-th neuron in layer d,

$${w}_{ij}^{d}$$

is a weight from the i-th neuron in layer d to the j-th neuron in layer d+1,

$${α}_{j}^{d + 1}$$

represents a threshold of the j-th neuron in layer d+1, and

$${x}_{j}^{d}$$

is an input received by the j-th neuron in layer d.

The MLP employs a backpropagation algorithm to train the weights between neurons in each layer, with a weight update formula as follows:

$${w}_{ij}^{( h )} ( new ) = {w}_{ij}^{( h )} ( old ) - μ \frac{\partial {Δ}^{2}}{\partial {w}_{ij}^{( h )}}$$

where

$${w}_{ij}^{( h )} ( new )$$

is an updated weight in layer h,

$${w}_{ij}^{( h )} ( old )$$

is a weight in layer h before updating, μ is a learning rate, and Δ is a difference between a current output and a target output of the output layer.

An embodiment of the disclosure further provides a schematic structural diagram of a computer device. As shown in FIG. 7, the computer device comprises: one or more processors 10, a memory 20, and interfaces for connecting various components, including high-speed interfaces and low-speed interfaces. The various components communicate with each other via different buses and may be mounted on a common motherboard or otherwise installed as needed. The processor may process instructions executed within the computer device, including instructions stored in or on the memory to display graphical information of a graphical user interface (GUI) on an external input/output device (e.g., a display device coupled to an interface). In some optional implementations, if necessary, multiple processors and/or multiple buses may be used together with multiple memories. Likewise, multiple computer devices may be connected, each providing part of the necessary operations (e.g., as a server array, a set of blade servers, or a multi-processor system). FIG. 7 illustrates a single processor 10 as an example.

The processor 10 may be a central processing unit, a network processor, or a combination thereof. The processor 10 may further include a hardware chip. The hardware chip may be an application-specific integrated circuit, a programmable logic device, or a combination thereof. The programmable logic device may be a complex programmable logic device, a field-programmable gate array, a generic array logic, or any combination thereof.

The memory 20 stores instructions executable by at least one processor 10 to cause the at least one processor 10 to perform the methods illustrated in the above embodiments.

The memory 20 may include a program storage area and a data storage area. The program storage area may store an operating system and an application program required for at least one function. The data storage area may store data created according to use of the computer device, among others. Furthermore, the memory 20 may include a high-speed random access memory and may also include a non-transitory memory, such as at least one magnetic disk storage device, a flash memory device, or other non-transitory solid-state storage device. In some optional implementations, the memory 20 may optionally include a memory remote from the processor 10, and such remote memories may be connected to the computer device via a network. Examples of such networks include, but are not limited to, the Internet, an intranet, a local area network, a mobile communication network, and combinations thereof.

The memory 20 may include a volatile memory, such as a random access memory. The memory may also include a non-volatile memory, such as a flash memory, a hard disk, or a solid-state drive. The memory 20 may further include a combination of the above types of memories.

The computer device further includes an input device 30 and an output device 40. The processor 10, the memory 20, the input device 30, and the output device 40 may be connected via a bus or other means. FIG. 7 illustrates a bus connection as an example.

The input device 30 may receive input numeric or character information and generate key signal inputs related to user settings and function control of the computer device, such as a touch screen, a keypad, a mouse, a trackpad, a touchpad, a pointing stick, one or more mouse buttons, a trackball, a joystick, or the like. The output device 40 may include a display device, an auxiliary lighting device (e.g., an LED), a tactile feedback device (e.g., a vibration motor), or the like. The display device includes, but is not limited to, a liquid crystal display, a light emitting diode display, a display, and a plasma display. In some optional implementations, the display device may be a touch screen.

An embodiment of the disclosure further provides a computer-readable storage medium. The methods according to the embodiments of the disclosure described above may be implemented in hardware or firmware, or implemented as computer code recordable on a storage medium, or implemented as computer code originally stored in a remote storage medium or a non-transitory machine-readable storage medium and downloaded via a network to be stored in a local storage medium. Thus, the methods described herein may be processed by software stored on a storage medium using a general-purpose computer, a special-purpose processor, or programmable or special-purpose hardware. The storage medium may be a magnetic disk, an optical disk, a read-only memory, a random access memory, a flash memory, a hard disk, a solid-state drive, or the like. Further, the storage medium may also include a combination of the above types of memories. It will be appreciated that a computer, a processor, a microcontroller, or programmable hardware includes storage components capable of storing or receiving software or computer code, and when the software or computer code is accessed and executed by the computer, processor, or hardware, the methods illustrated in the above embodiments are implemented.

A portion of the disclosure may be embodied as a computer program product, for example, computer program instructions, which, when executed by a computer, may invoke or provide the methods and/or technical solutions according to the disclosure through the operation of the computer. Those skilled in the art will appreciate that computer program instructions may exist in a computer-readable medium in various forms including, but not limited to, source files, executable files, installation package files, and the like. Accordingly, the manners in which computer program instructions are executed by a computer include, but are not limited to: the computer executing the instructions directly, the computer compiling the instructions and then executing the corresponding compiled program, the computer reading and executing the instructions, or the computer reading and installing the instructions and then executing the corresponding installed program. In this context, a computer-readable medium may be any available computer-readable storage medium or communication medium accessible by a computer.

It will be obvious to those skilled in the art that changes and modifications may be made, and therefore, the aim in the appended claims is to cover all such changes and modifications.

What is claimed is:

1. A TinyML-based motor condition monitoring method, applied to a microcontroller unit of an edge device in an HVAC system, the method comprising:
collecting real-time operating parameters of a monitored motor;
preprocessing the real-time operating parameters to convert the real-time operating parameters into input data having a preset format, wherein the preset format is a data input format of a TinyML model pre-deployed in the microcontroller unit; and
inputting the input data into the TinyML model, and outputting, by the TinyML model, a real-time condition monitoring result of the monitored motor.

2. The method of claim 1, further comprising:
after outputting the real-time condition monitoring result of the monitored motor by the TinyML model, adjusting an operation action of the monitored motor according to the real-time condition monitoring result.

3. The method of claim 2, wherein adjusting the operation action of the monitored motor according to the real-time condition monitoring result comprises:
determining whether the real-time condition monitoring result is a first type of abnormal condition; and
if the real-time condition monitoring result is the first type of abnormal condition, changing a rotation speed or a start/stop status of the monitored motor, or outputting alarm information.

4. The method of claim 3, wherein adjusting the operation action of the monitored motor according to the real-time condition monitoring result further comprises:
determining whether the real-time condition monitoring result is a second type of abnormal condition; and
if the real-time condition monitoring result is the second type of abnormal condition, sending maintenance warning information to a third-party platform, wherein the maintenance warning information comprises the real-time condition monitoring result, an identity identifier of the monitored motor, and location information of the monitored motor.

5. The method of claim 4, wherein adjusting the operation action of the monitored motor according to the real-time condition monitoring result further comprises:
determining whether the real-time condition monitoring result is a third type of abnormal condition; and
if the real-time condition monitoring result is the third type of abnormal condition, sending the collected real-time operating parameters to the third-party platform, and causing the third-party platform to re-determine the condition of the monitored motor according to the real-time operating parameters using a preset artificial intelligence model, wherein the preset artificial intelligence model has a larger scale or higher recognition accuracy than the TinyML model.

6. The method of claim 1, wherein the TinyML model is a classification model based on a convolutional neural network trained by supervised learning, wherein training samples comprise three-phase currents corresponding to a shaft balanced state of the motor and three-phase currents corresponding to a shaft imbalanced state of the motor, and the real-time operating parameters are real-time three-phase currents of the monitored motor; and
correspondingly, inputting the input data into the TinyML model and outputting, by the TinyML model, the real-time condition monitoring result of the monitored motor comprises:
inputting the input data into the TinyML model, and outputting, by the TinyML model, a classification result of the monitored motor; and
if the classification result is the shaft balanced state, outputting the real-time condition monitoring result as a normal state, or if the classification result is the shaft imbalanced state, outputting the real-time condition monitoring result as an abnormal state.

7. The method of claim 6, wherein the classification model employs a multilayer perceptron; the multilayer perceptron comprises an input layer, hidden layers, and an output layer; the input layer is configured to receive features of the input data; and the hidden layers and the output layer use a nonlinear activation function, and input and output of each of the hidden layers and the output layer are respectively expressed as:
$$\begin{matrix}{x}_{j}^{d + 1} = {\sum }_{i = 1}^{n} {y}_{i}^{d} {w}_{ij}^{d} - {α}_{j}^{d + 1} \\ {y}_{j}^{d} = \frac{1}{1 + {e}^{- {x}_{j}^{d}}}\end{matrix}$$
where
$${x}_{j}^{d + 1}$$
is an input received by an j-th neuron in layer d+1, n is a number of input features,
$${y}_{i}^{d}$$
is an output of an i-th neuron in layer d,
$${w}_{ij}^{d}$$
is a weight from the i-th neuron in layer d to the j-th neuron in layer d+1,
$${α}_{j}^{d + 1}$$
represents a threshold of the j-th neuron in layer d+1, and
$${x}_{j}^{d}$$
is an input received by the j-th neuron in layer d; and
the MLP employs a backpropagation algorithm to train weights between neurons in each layer, with a weight update formula as follows:
$${w}_{ij}^{( h )} ( new ) = {w}_{ij}^{( h )} ( old ) - μ \frac{\partial {Δ}^{2}}{\partial {w}_{ij}^{( h )}}$$
where
$${w}_{ij}^{( h )} ( new )$$
is an updated weight in layer h,
$${w}_{ij}^{( h )} ( old )$$
is a weight in layer h before updating, μ is a learning rate, and Δ is a difference between a current output and a target output of the output layer.

8. A TinyML-based motor condition monitoring apparatus, applied to a microcontroller unit of an edge device in an HVAC system, the apparatus comprising:
a parameter acquisition module configured to collect real-time operating parameters of a monitored motor;
a data preprocessing module configured to preprocess the real-time operating parameters to convert the real-time operating parameters into input data having a preset format, wherein the preset format is a data input format of a TinyML model pre-deployed in the microcontroller unit; and
a result detection module configured to input the input data into the TinyML model, and output, by the TinyML model, a real-time condition monitoring result of the monitored motor.

9. A computer device, comprising: a memory and a processor, wherein the memory and the processor are communicatively connected to each other, the memory stores computer instructions, and the processor executes the computer instructions to perform the TinyML-based motor condition monitoring method of claim 1.

10. A computer-readable storage medium, wherein the computer-readable storage medium stores computer instructions, and the computer instructions are configured to cause a computer to perform the TinyML-based motor condition monitoring method of claim 1.
